(19) United States
(12) Patent Application Publication
(10) Pub. No.: US 2026/0283051 A1
(43) Pub. Date: Sep. 17, 2026

(54) AIR CAVITY LID

(71) Applicant: Qorvo US, Inc., Greensboro, NC (US)

(72) Inventors: MD Hasnine, Richardson, TX (US); Charles E. Carpenter, Orlando, FL (US)

(21) Appl. No.: 19/535,078

(22) Filed: Feb. 10, 2026

Related U.S. Application Data
(60) Provisional application No. 63/773,089, filed on Mar. 17, 2025.

(51) Int. Cl. H10W 90/00; H10W 74/15

(52) U.S. Cl. CPC H10W 90/724; H10W 74/15

(57) ABSTRACT

An air cavity lid is disclosed. In one aspect, a semiconductor die is placed on a laminate and a lid is placed thereover to form an air cavity. The lid is attached to the laminate. To assist in preventing the bond between the lid and the laminate from failing (e.g., during a subsequent reflow step), the lid includes one or more surface area expanding features. These features expand the amount of surface area available to attach to bonding material, thereby increasing the mechanical bond between the laminate and the lid. This increased bond helps assure passage of gross leak testing after subsequent processing steps (e.g., reflow).

### PRIORITY APPLICATION

The present application is related to U.S. Provisional Patent Application Serial No. 63/773,089, filed on Mar. 17, 2025, and entitled “AIR CAVITY LID,” the contents of which are incorporated herein by reference in their entirety.

### BACKGROUND

### I. Field of the Disclosure

The technology of the disclosure relates generally to semiconductor packages and more particularly to lids used to create air cavities on laminates that have semiconductors thereon.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find better processing of data and signals. This pressure has led to the adoption of semiconductor packages that have an air cavity over a semiconductor die attached to a laminate. Laminate air cavity packages are used in many applications due to air’s superior dielectric properties at the frequencies of interest. Finding better ways to attach lids that create such air cavities provides room for innovation.

### SUMMARY

Aspects disclosed in the detailed description include an air cavity lid. In particular, a semiconductor die is placed on a laminate, and a lid is placed thereover to form an air cavity. The lid is attached to the laminate. To assist in preventing the bond between the lid and the laminate from failing (e.g., during a subsequent reflow step), the lid includes one or more surface area expanding features. These features expand the amount of surface area available to attach to bonding material, thereby increasing the mechanical bond between the laminate and the lid. This increased bond helps ensure passage of gross leak testing after subsequent processing steps (e.g., reflow).

In this regard, in one aspect, a package is disclosed. The package includes a substrate, a die positioned on the substrate, and a lid positioned over the substrate and delimiting an air cavity in which the die is located, the lid comprising a lid sidewall bonded to the substrate with a lid seal epoxy, the lid sidewall comprising a surface area expanding feature.

In another aspect, a communication device is disclosed. The communication device includes a transceiver comprising a package. The package includes a substrate, a die positioned on the substrate, and a lid positioned over the substrate and delimiting an air cavity in which the die is located, the lid comprising a lid sidewall bonded to the substrate with a lid seal epoxy, the lid sidewall comprising a surface area expanding feature.

In another aspect, method for forming a package is disclosed. The method includes forming a lid comprising a lid sidewall with a surface area expanding feature, attaching the lid to a substrate with a lid seal epoxy, and using an underfill material to provide a secondary bond between the lid and the substrate.

### BRIEF DESCRIPTION OF THE DRAWINGS

FIG. 1 is a side cross-sectional view of a conventional package with a lid attached to a laminate;

FIG. 2 is a side cross-sectional view of a first lid according to the present disclosure;

FIG. 3 is a flowchart describing the formation and installation of the lid of FIG. 2;

FIGS. 4A-4L are side cross-sectional views of the lid during the process of FIG. 3;

FIG. 5 is a side cross-sectional view of a second lid according to the present disclosure;

FIG. 6 is a flowchart describing the formation and installation of the lid of FIG. 5;

FIGS. 7A-7E are side cross-sectional views of the lid during the process of FIG. 6;

FIG. 8 is a side cross-sectional view of a third lid according to the present disclosure;

FIG. 9 is a flowchart describing the formation and installation of the lid of FIG. 8;

FIGS. 10A-10E are side cross-sectional views of the lid during the process of FIG. 9;

FIG. 11 is a side cross-sectional view of a fourth lid according to the present disclosure;

FIG. 12 is a flowchart describing the formation and installation of the lid of FIG. 11;

FIGS. 13A-13H are side cross-sectional views of the lid during the process of FIG. 12;

FIG. 14 is a side cross-sectional view of a fifth lid according to the present disclosure;

FIG. 15 is a side cross-sectional view of the lid assembled with the laminate; and

FIG. 16 is a block diagram of a mobile communication device, which may include a package having an air cavity and lid of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a," “an,” and “the” are intended to include the plural forms as well unless the context clearly indicates otherwise. It will be further understood that the terms “comprises," “comprising," “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include an air cavity lid. In particular, a semiconductor die is placed on a laminate and a lid is placed thereover to form an air cavity. The lid is attached to the laminate. To assist in preventing the bond between the lid and the laminate from failing (e.g., during a subsequent reflow step), the lid includes one or more surface area expanding features. These features expand the amount of surface area available to attach to bonding material, thereby increasing the mechanical bond between the laminate and the lid. This increased bond helps assure passage of gross leak testing after subsequent processing steps (e.g., reflow).

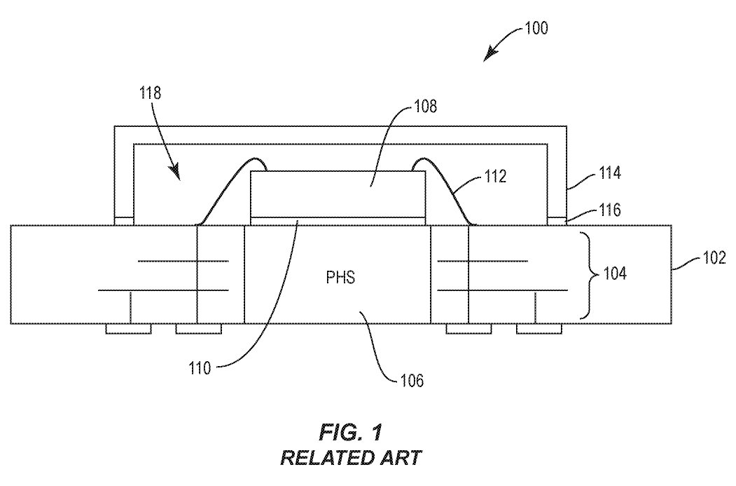

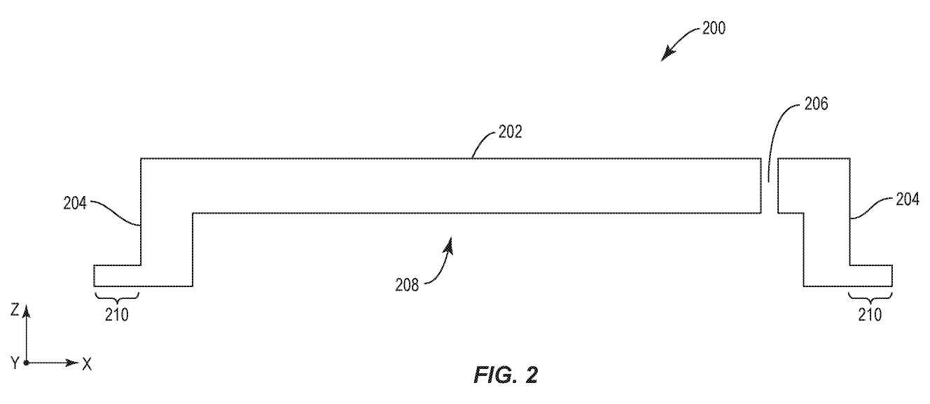

Before addressing aspects of the present disclosure, a brief overview of a conventional package having an air cavity is provided with reference to FIG. 1. A discussion of aspects of the present disclosure begins below with reference to FIG. 2.

In this regard, FIG. 1 illustrates a package 100 having a laminate 102 with internal metallization layers 104 and a plated heat spreader (PHS) 106 therein. A chip or die 108 is positioned on a top surface of the laminate 102 and attached thereto with a sintering material 110. Wirebonds 112 electrically couple the circuitry (not shown) within the die 108 to the internal metallization layers 104. A lid 114 is positioned over the die 108 and bonded to the top surface of the laminate 102 with an epoxy 116 and forms an air cavity 118. The die 108 is positioned in the air cavity 118. The air cavity 118 may be well-suited in radio frequency (RF) applications because of the dielectric properties of air (especially as compared to a solid mold compound).

An essential function and purpose of the lid 114 is to keep the air cavity 118 isolated from liquid to protect the die 108 from corrosion and generally maintain RF performance. As noted above, laminate air cavity packages are used in many applications due to air's superior dielectric properties compared to mold compound-based packages, offering significant RF performance advantages. In RF air cavity packages, plastic lids are typically used. However, these plastic air cavity packages are vulnerable to gross leak testing under environmental conditions such as moisture sensitivity level (MSL) pre-conditioning. During board-level assembly, the cavity package undergoes multiple reflows and aqueous washes. Adhering to MSL and gross leak (GL) standards ensures that liquids cannot enter the cavity, thereby protecting the package from corrosion and maintaining RF performance. In typical air cavity packages, lid sealing epoxies (e.g., epoxy 116) are dispensed on the laminate wall, followed by lid placement, and curing. This process is not robust and can cause GL failure after exposure to MSL pre-conditioning. Given that plastic air cavity packages are more susceptible to GL, a robust lid attach design and solution are needed to make the cavity package resistant to GL and enhance RF performance.

Aspects of the present disclosure contemplate a lid wall design that includes increased surface area to which the epoxy material may bond, improving the bond between the lid and the laminate. In exemplary aspects, the increase in surface area may be formed by a trench or shoulder on the lid wall. Additional underfill or encapsulant material may be used to provide additional adhesion and mechanical anchoring to enhance lid integrity. The lid of the present disclosure may be made from an FR4 material and may be routed into a desired shape prior to singulation.

In this regard, FIG. 2 illustrates a lid 200 according to a first aspect of the present disclosure. The lid 200 includes a top 202 and lid sidewalls 204. While two lid sidewalls 204 are illustrated, it should be appreciated that most lids are rectilinear and have four distinct lid sidewalls, although circular or other shapes are possible. Regardless of precise shape, each lid 200 will have lid sidewalls 204 around the entirety of the outer periphery of the top 202. The top 202 may have a vent hole 206 that extends from an exterior portion of the lid 200 into an air cavity 208. The surface area feature for the lid 200 is a lid wall extension 210 that extends outwardly from the lid sidewalls 204. In an exemplary aspect, the lid sidewall 204 extends along the z-axis (up-down) and the lid wall extension 210 extends outwardly in the x-y plane at a right (90) degree angle thereto. In an exemplary aspect, the lid wall extension 210 is approximately 20-30% of the lid sidewall 204 width. Thus, if the lid sidewall 204 is 300 micrometers wide (x-axis), the lid wall extension 210 would be another 60-90 micrometers. The vent hole 206 may have a diameter of approximately 50 to 80 micrometers.

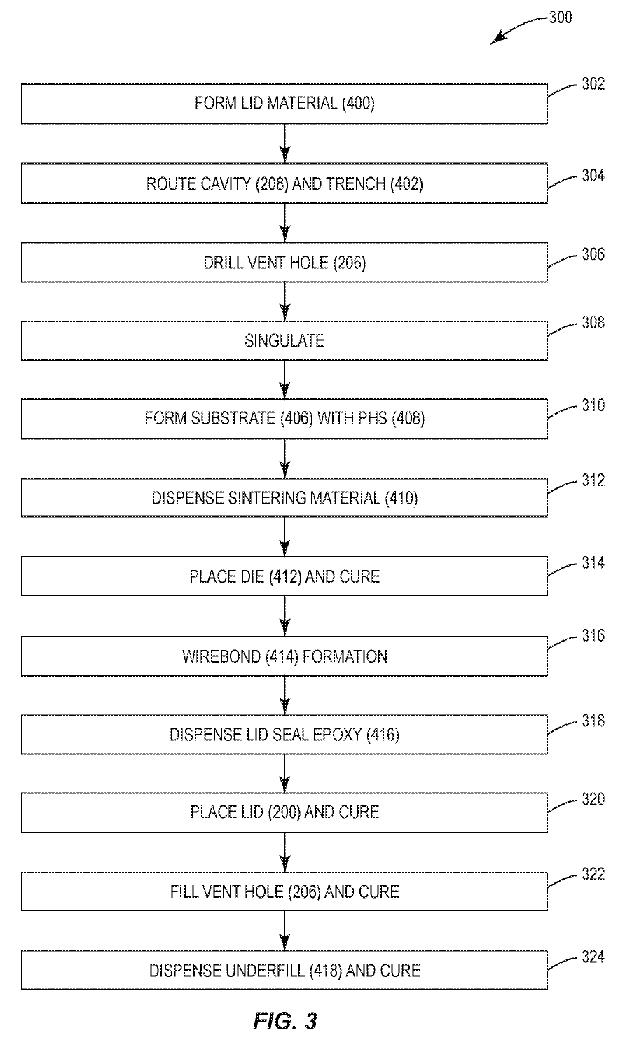

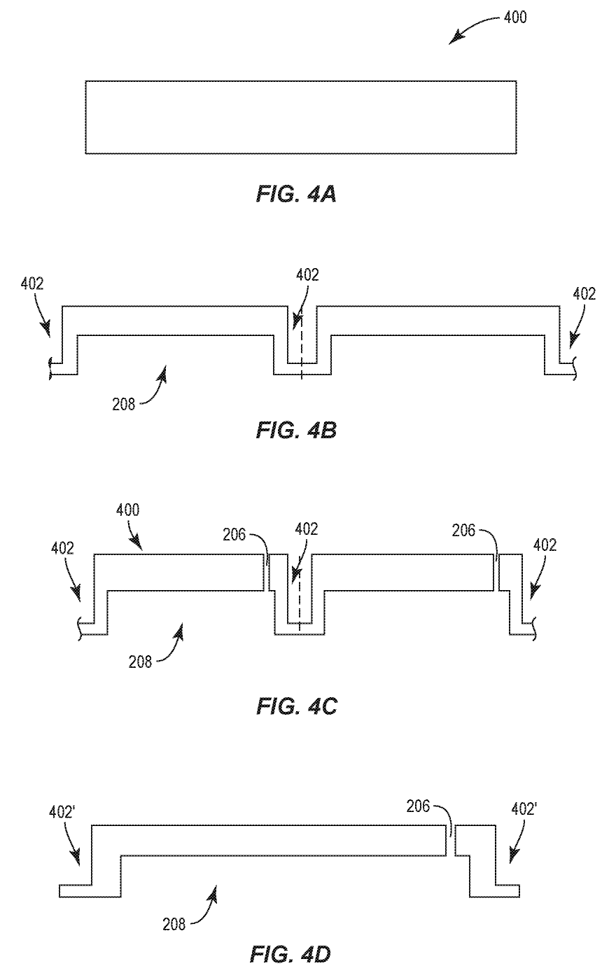

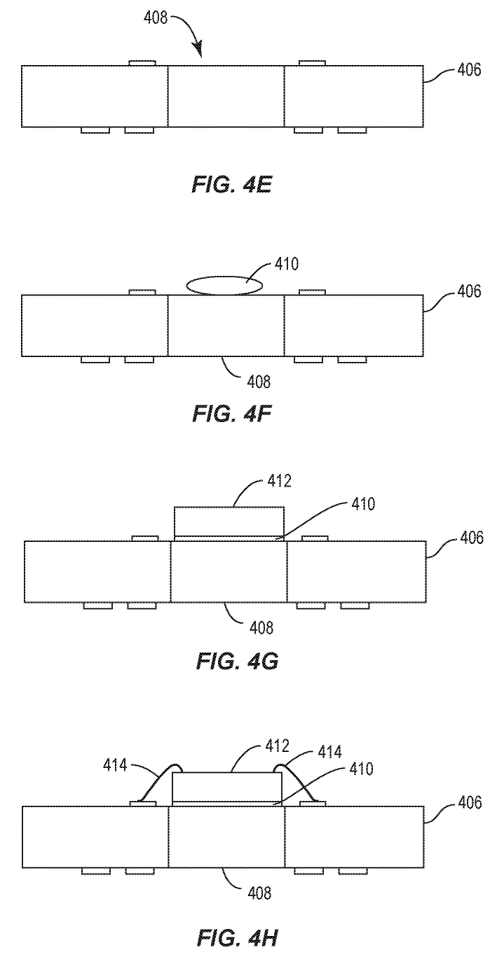

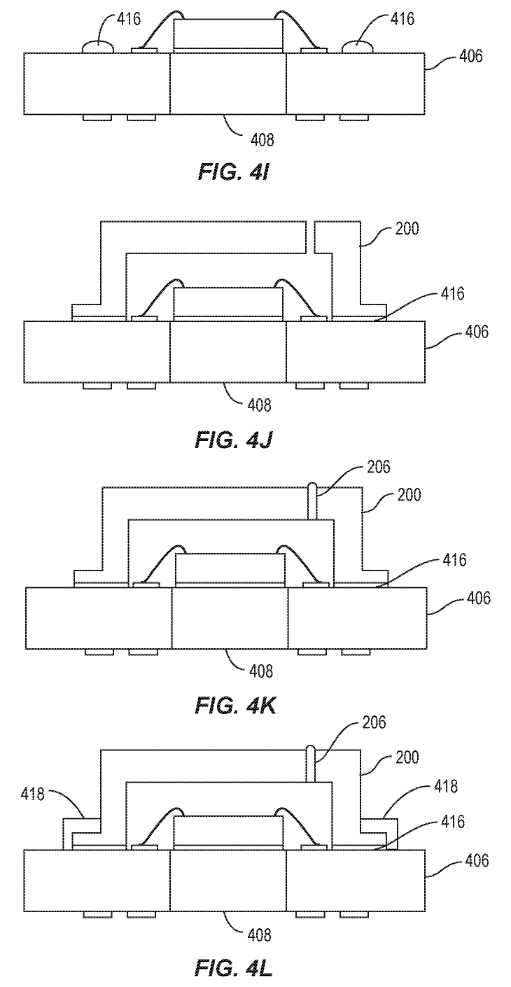

FIG. 3 illustrates a process 300 for forming the lid 200 and joining the lid 200 into a package. FIGS. 4A-4L illustrate the various stages of the formation and assembly and the following discussion switches back and forth between the various Figures.

In this regard, the process 300 begins with the formation of the lid material 400 (block 302, see FIG. 4A). The lid material 400 may be FR4 material or the like and may be a laminate. The cavity 208 and a trench 402 are routed into the lid material 400 (block 304, see FIG. 4B). A vent hole 206 is drilled (block 306, see FIG. 4C) through the lid material 400. The lid material 400 is then singulated (block 308, see FIG. 4D), which splits the trenches 402 into partial trenches 402’ that have a lid wall extension.

Potentially concurrently, a substrate 406 with a PHS 408 is formed (block 310, see FIG. 4E). A sintering material 410 is dispensed on the PHS 408 (block 312, see FIG. 4F). A die 412 is placed and the sintering material 410 is cured (block 314, see FIG. 4G). Wirebonds 414 are formed (block 316, see FIG. 4H) coupling the circuitry within the die 412 to internal metallization layers (not shown) in the substrate 406. A lid seal epoxy 416 is dispensed (block 318, see FIG. 4I). In an exemplary aspect, the lid seal epoxy 416 may be a low modulus (e.g., approximately 5-50 MPa).

At this point, the steps for lid formation and the substrate assembly converge and the lid 200 is placed on the substrate 406 and cured (block 320, see FIG. 4J). The lid seal epoxy 416 extends across not just the width of the lid sidewalls 204 but also extends across the surface area feature of the lid wall extension 210, creating a bond across more surface area and, it is believed, forming a stronger bond between the lid 200 and the substrate 406. The vent hole 206 is then filled and cured (block 322, see FIG. 4K). The vent hole 206 was present to allow outgassing for the cavity 208 but is not needed for later steps. To assist further in making a strong bond, an underfill material 418 dispensed and cured (block 324, see FIG. 4L). Note that in an exemplary aspect, the underfill material 418 forms a bond with the substrate 406 and flows up and over the lid wall extension 210 forming a secondary barrier to maintain the leak integrity of the cavity 208 (i.e., the underfill barrier and the lid seal epoxy 416 barrier).

Thus, the lid wall extension 210 has, in effect, two surface area expanders. The first is the additional surface area to which the lid seal epoxy 416 may adhere. The second is the vertical surface and additional horizontal top surface of the lid wall extension 210. Both features add to the strength of the bond formed between the lid 200 and the substrate 406.

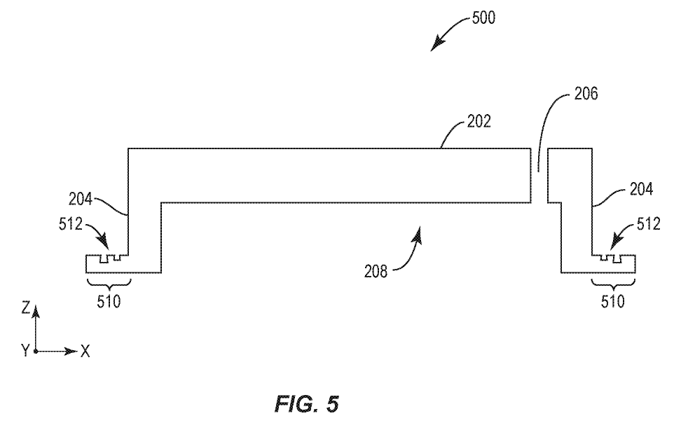

While the lid wall extension 210 is one way in which the surface area may be expanded, it is not the only way. FIGS. 5, 8, 11, 14 and 15 all provide alternate exemplary structures.

In this regard, FIG. 5 illustrates a lid 500 with a roughened lid wall extension 510. That is, an upper surface 512 of the lid wall extension 510 has been roughened by mechanical grinding, laser ablation, or the like to increase the adhesion/provide more anchor points. The remaining portions of the lid 500 are essentially identical to lid 200 and not renumbered.

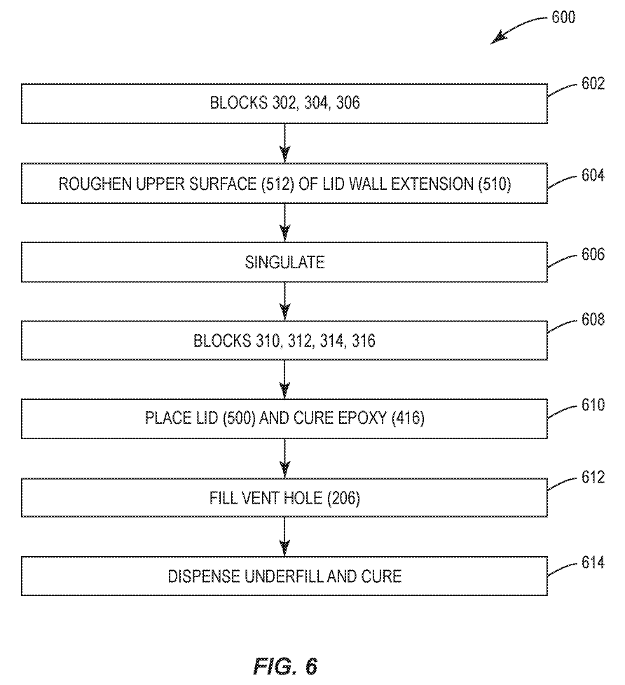

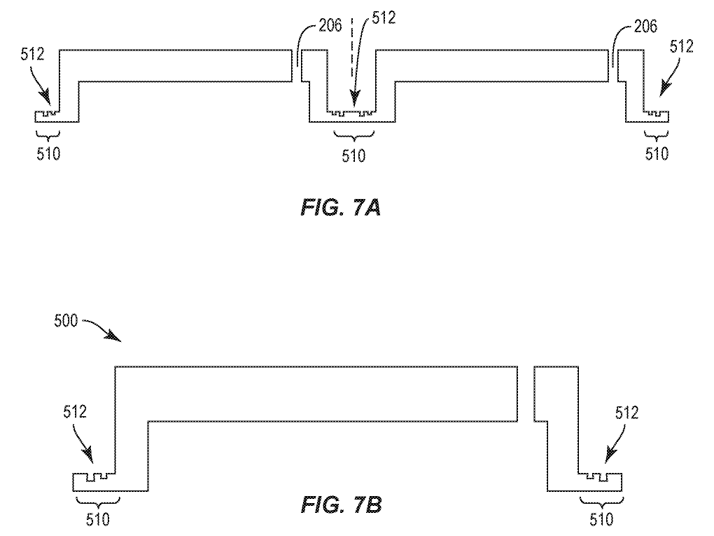

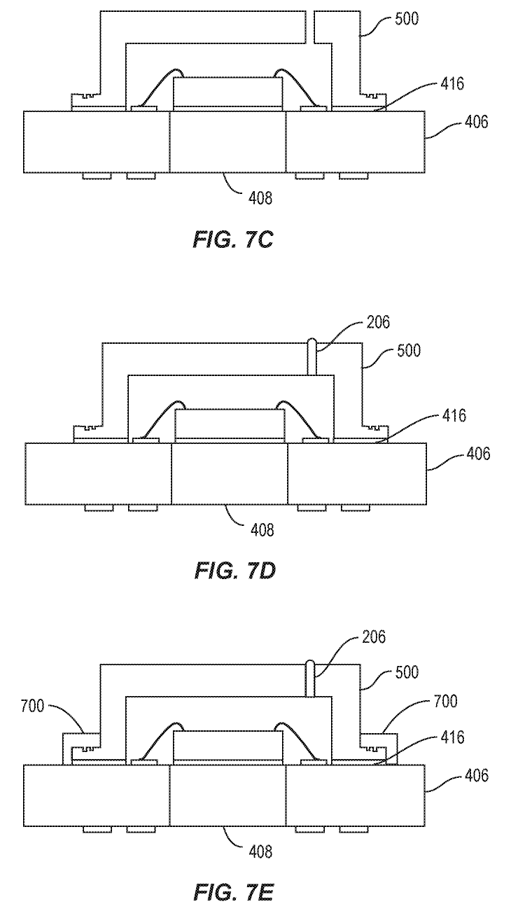

FIG. 6 provides a flowchart of a process 600 for forming the lid 500 and package. FIGS. 7A-7E are used to illustrate various steps of the process 600. Note that many steps are essentially identical to those of process 300 and explanations are not repeated in full.

In this regard, the process 600 begins with blocks 302, 304, and 306 of the process 300 (block 602). The upper surface 512 of the lid wall extension 510 is roughened (block 604, see FIG. 7A) and the lid material is singulated (block 606, see FIG. 7B) to form lid 500. Blocks 310, 312, 314, and 316 are performed (block 608). Again, these steps may be done concurrently with lid formation or sequentially (either before or after). The lid 500 is placed on the lid seal epoxy 416 and the lid seal epoxy 416 is cured (block 610, see FIG. 7C). The vent hole 206 is filled and cured (block 612, see FIG. 7D). An underfill material 700 is dispensed and cured (block 614, see FIG. 7E). Note that the underfill material 700 may flow into the roughened portions of the upper surface 512, thereby creating a stronger bond because there is more surface area.

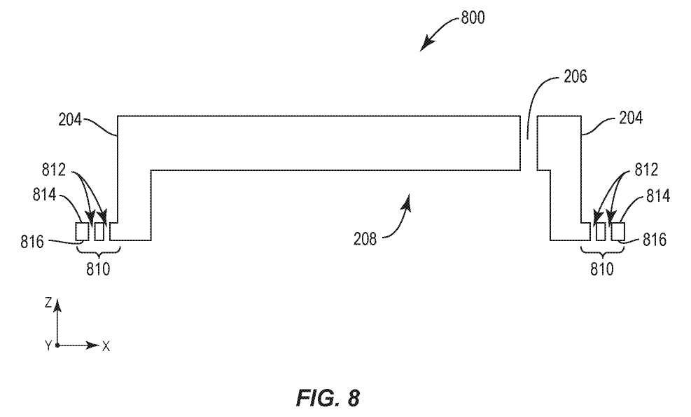

Instead of merely roughening the upper surface, a further aspect may drill all the way through the lid wall extension 810 as shown by lid 800 in FIG. 8. More particularly through holes 812 may extend from an upper surface 814 to a lower surface 816 of the lid wall extension 810.

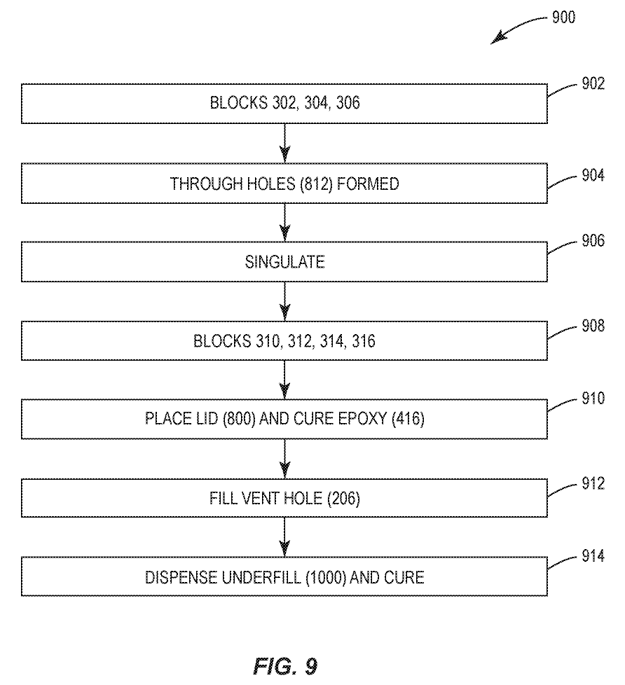

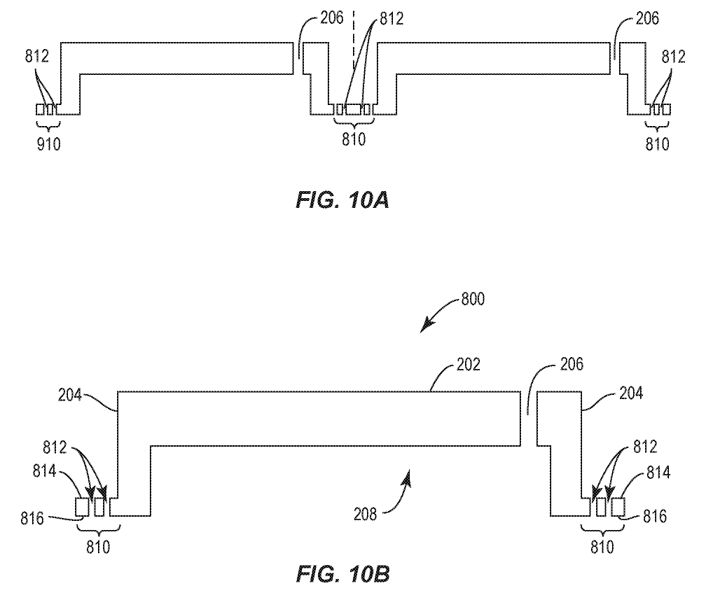

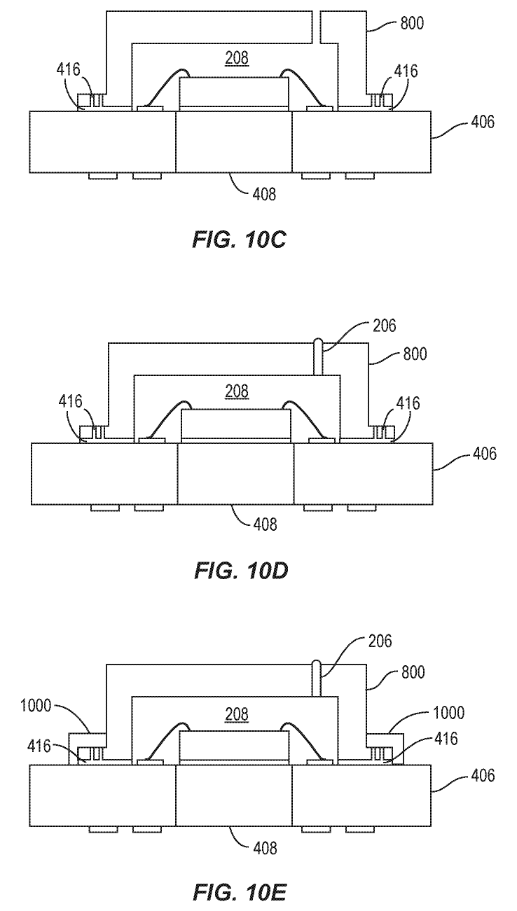

The lid 800 may be formed by a process 900 illustrated in FIG. 9 with supporting FIGS. 10A-10E. The process 900 is similar to the process 300 and 600.

The process 900 begins with blocks 302, 304, and 306 of the process 300 (block 902). Through holes 812 are formed in the lid wall extension 810 (block 904, see FIG. 10A) and the lid material is singulated (block 906, see FIG. 10B) to form lid 800. Blocks 310, 312, 314, and 316 are performed (block 908). Again, these steps may be done concurrently with lid formation or sequentially (either before or after). The lid 800 is placed on the lid seal epoxy 416 and the lid seal epoxy 416 is cured (block 910, see FIG. 10C). Note that the lid seal epoxy 416 may flow up into the through holes 812, increasing the bonding surface area. The vent hole 206 is filled and cured (block 912, see FIG. 10D). An underfill material 1000 is dispensed and cured (block 914, see FIG. 10E).

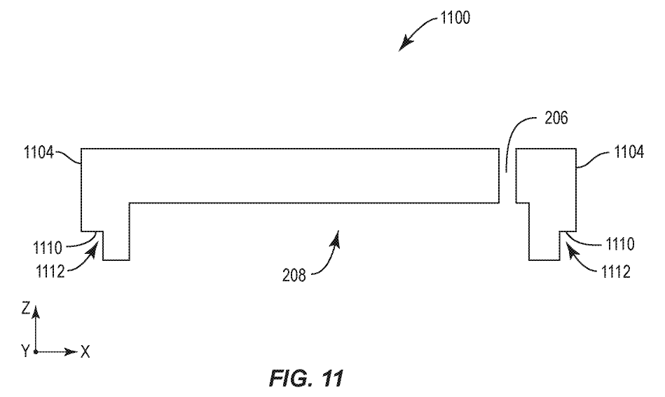

Instead of a lid extension wall as shown in lids 200, 500, and 800, the surface area feature may instead be a shelf or ledge as better shown by lid 1100 in FIG. 11. In this regard, the lid 1100 may be made of the same materials as the lids 200, 500, 800 (e.g., FR4) and may have the same general thickness dimensions. However, the lid sidewalls 1104 do not have a lid wall extension. Instead, a shelf 1110 is cut into the lid sidewalls 1104 at the bottom edge. This adds a vertical surface 1112 to the total surface area available for bonding. During formation and before singulation, this shelf 1110 may look like a trench and thus may sometimes be referred to as such.

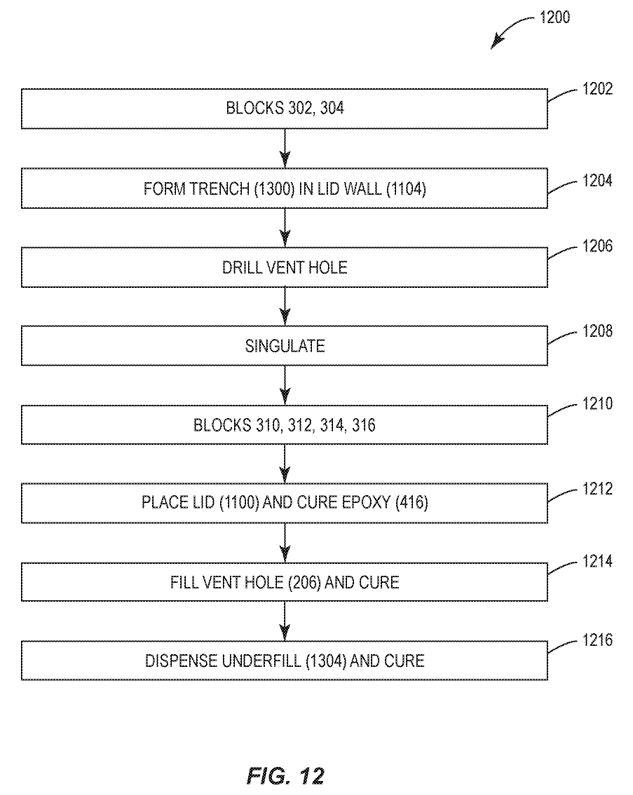

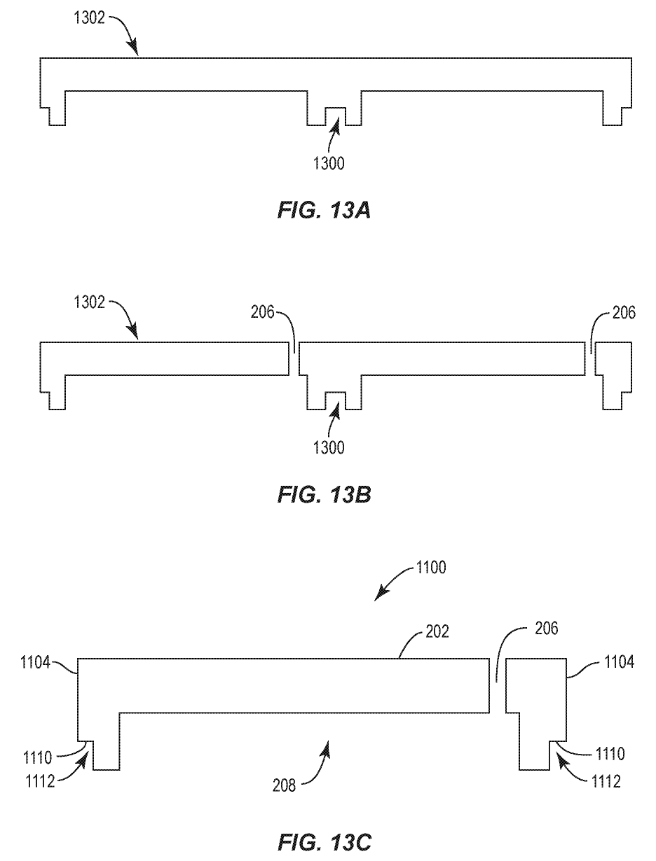

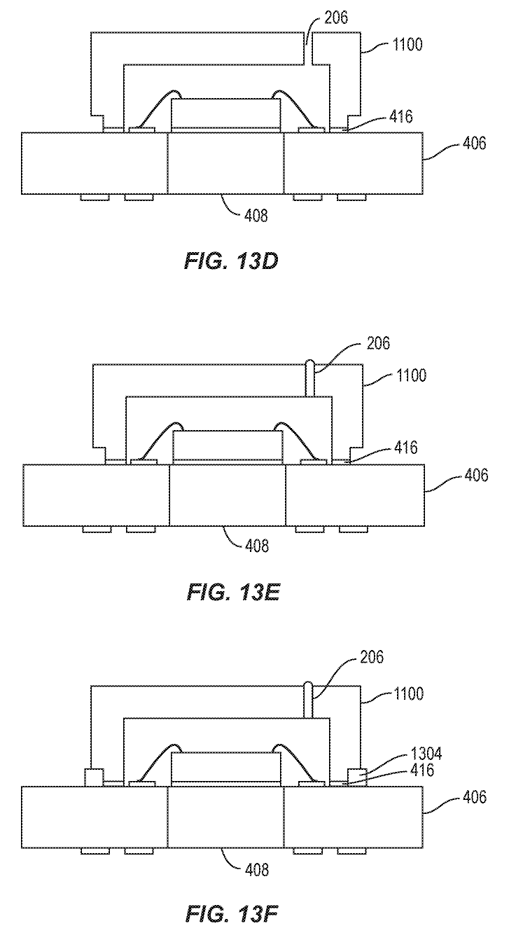

FIG. 12 provides a flowchart for a process 1200 for the formation and use of the lid 1100 with additional reference to FIGS. 13A-13F. The process 1200 begins with blocks 302 and 304 of the process 300 (block 1202). A trench 1300 is formed (block 1204, see FIG. 13A) in the portion of the material 1302 that will eventually form the sidewalls 1104. This trench 1300 may be formed by drilling, polishing, routing, or similar techniques. The vent hole 206 is drilled (block 1206, see FIG. 13B) and the lid material is singulated (block 1208, see FIG. 13C) to form lid 1100. After singulation, the lid sidewalls 1104 are no longer merged with the neighboring lids and the trench 1300 splits to form the shelf 1110.

Blocks 310, 312, 314, and 316 are performed (block 1210). Again, these steps may be done concurrently with lid formation or sequentially (either before or after). The lid 1100 is placed on the lid seal epoxy 416 and the lid seal epoxy 416 is cured (block 1212, see FIG. 13D). The vent hole 206 is filled and cured (block 1214, see FIG. 13E). An underfill material 1304 is dispensed and cured (block 1216, see FIG. 13F). The underfill material 1304 bonds to the horizontal surface of the shelf 1110 as well as the vertical surface 1112 thereby having more surface area with which to create a bond. Note that this aspect may be appropriate where the lateral space on the surface of the substrate 406 is limited.

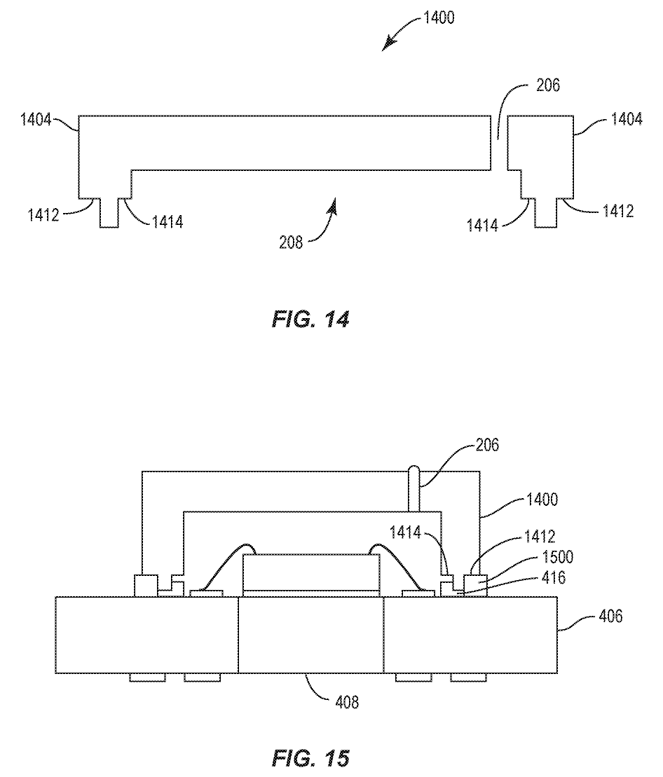

Note that it is also possible to have shelves on both sides of the sidewalls as better seen by lid 1400 in FIG. 14. The lid sidewalls 1404 each have an external shelf 1412 and an internal shelf 1414 to assist in creating the surface area feature of the present disclosure. In use, as shown in FIG. 15, the lid seal epoxy 416 may bond to the interior vertical surface and potentially to the internal shelf 1414 (not shown) and the underfill material 1500 may bond to the external shelf 1412 and the external vertical surface.

The lids according to aspects disclosed herein, may be provided in or integrated into any processor-based device that has an air cavity package. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

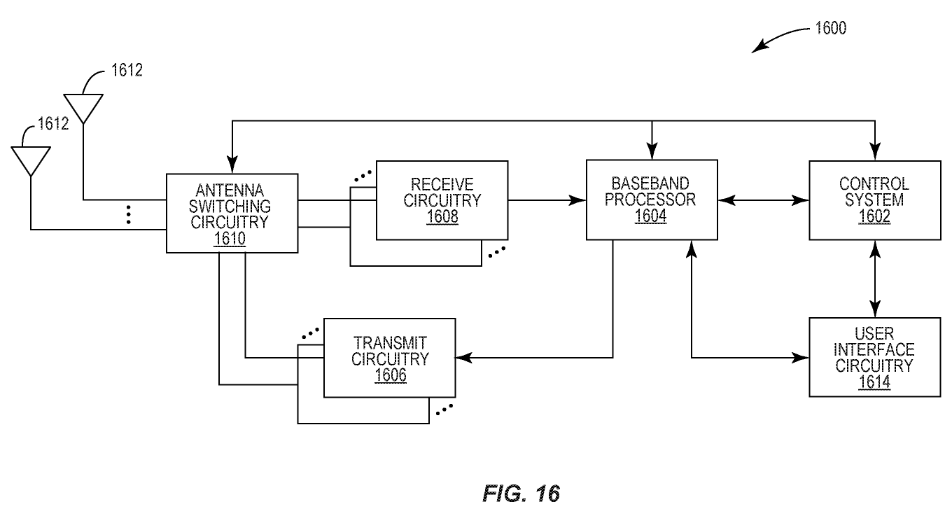

FIG. 16 is a schematic diagram of an exemplary communication device 1600 wherein packages containing the air cavities defined by the lid of the present disclosure be provided. Herein, the communication device 1600 can be any type of communication device, such as those listed above as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 1600 will generally include a control system 1602, a baseband processor 1604, transmit circuitry 1606, receive circuitry 1608, antenna switching circuitry 1610, multiple antennas 1612, and user interface circuitry 1614. In a non-limiting example, the control system 1602 can be a field-programmable gate array (FPGA) or an application-specific integrated circuit (ASIC), as an example. In this regard, the control system 1602 can include at least a microprocessor(s), an embedded memory circuit(s), and a communication bus interface(s). The receive circuitry 1608 receives radio frequency signals via the antennas 1612 and through the antenna switching circuitry 1610 from one or more base stations. A low noise amplifier and a filter of the receive circuitry 1608 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1604 processes the digitized received signal to extract the information or data bits conveyed in the received signal. This processing typically comprises demodulation, decoding, and error correction operations. The baseband processor 1604 is generally implemented in one or more digital signal processors (DSPs) and ASICs.

For transmission, the baseband processor 1604 receives digitized data, which may represent voice, data, or control information, from the control system 1602, which it encodes for transmission. The encoded data is output to the transmit circuitry 1606, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1612 through the antenna switching circuitry 1610. The multiple antennas 1612 and the replicated transmit and receive circuitries 1606, 1608 may provide spatial diversity. Modulation and processing details will be understood by those skilled in the art. To the extent that it is not clear, any of the transceiver circuitry (e.g., the transmit circuitry 1606 and/or the receive circuitry 1608) may include packages formed according to the present disclosure.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A package comprising:
a substrate;
a die positioned on the substrate; and
a lid positioned over the substrate and delimiting an air cavity in which the die is located, the lid comprising a lid sidewall bonded to the substrate with a lid seal epoxy, the lid sidewall comprising a surface area expanding feature.

2. The package of claim 1, wherein the surface area expanding feature comprises a shelf.

3. The package of claim 2, wherein the shelf comprises an interior shelf.

4. The package of claim 2, wherein the shelf comprises an exterior shelf.

5. The package of claim 1, wherein the surface area expanding feature comprises a lid wall extension.

6. The package of claim 5, wherein the lid wall extension delimits a through hole.

7. The package of claim 6, wherein the lid seal epoxy extends into the through hole.

8. The package of claim 5, wherein the lid wall extension comprises a roughened upper surface.

9. The package of claim 5, further comprising an underfill material extending from the substrate and over the lid wall extension.

10. The package of claim 1, wherein the lid comprises an FR4 material.

11. A communication device comprising:
a transceiver comprising a package, the package comprising:
a substrate;
a die positioned on the substrate; and
a lid positioned over the substrate and delimiting an air cavity in which the die is located, the lid comprising a lid sidewall bonded to the substrate with a lid seal epoxy, the lid sidewall comprising a surface area expanding feature.

12. The communication device of claim 11 selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

13. A method for forming a package comprising:
forming a lid comprising a lid sidewall with a surface area expanding feature;
attaching the lid to a substrate with a lid seal epoxy; and
using an underfill material to provide a secondary bond between the lid and the substrate.

14. The method of claim 13, wherein forming the lid comprises cutting a trench prior to singulation.

15. The method of claim 13, wherein forming the lid comprises forming a shelf.

16. The method of claim 13, wherein forming the lid comprises forming a lid wall extension.

17. The method of claim 16, further comprising roughening the lid wall extension.

18. The method of claim 16, further comprising creating through holes in the lid wall extension.

19. The method of claim 18, further comprising bonding the lid seal epoxy to an interior surface of the through holes.

20. The method of claim 17, further comprising bonding a top surface of the lid wall extension with the underfill material.
